(19) United States
(12) Patent Application Publication
(10) Pub. No.: US 2013/0163216 A1
(43) Pub. Date: Jun. 27, 2013

(54) ATTACHMENT MECHANISM FOR ELECTRONIC COMPONENT

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/445,935

(22) Filed: Apr. 13, 2012

(30) Foreign Application Priority Data
Dec. 26, 2011 (CN) 201110440968.2

(51) Int. Cl. H05K 7/00

(52) U.S. Cl. 361/759

(57) ABSTRACT

An attachment mechanism for an electronic component includes a circuit board and a fastener. The circuit board includes a first connector to be connected to a second connector at a first end of the electronic component. The fastener includes a main body mounted on the first connector and two cantilevers extending from opposite ends of the main body. Two holding portions extend from distal ends of the cantilevers to hold opposite sides of the electronic component.

### CROSS-REFERENCE OF RELATED APPLICATIONS

Relevant subject matter is disclosed in four pending U.S. patent applications, all titled “ATTACHMENT MECHANISM FOR ELECTRONIC COMPONENT”, respectively filed on Mar. 22, 2012, with the application Ser. No. 13/426,629, on Mar. 23, 2012, with the application Ser. No. 13/427,923, on Mar. 29, 2012, with the application Ser. No. 13/434,791, and on Apr. 12, 2012, with the application Ser. No. 13/444,874, which are assigned to the same assignee as this patent application.

### BACKGROUND

1. Technical Field

The present disclosure relates to a mechanism for attaching an electronic component to a device.

2. Description of Related Art

Certain components in a server, such as expansion cards, need to be attached to the motherboard of the server. Taking such an expansion card for example, an end of the expansion card is fastened to the motherboard, and a connector at an opposite end of the expansion card is connected to a connector of the motherboard. However, the connection of the connectors may not be solid enough and the expansion card may disengage from the connector of the motherboard, which adversely influences the data transmission of the server.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an attachment mechanism, together with an electronic component, wherein the attachment mechanism includes a fastener.

FIG. 2 is an enlarged view of the fastener of FIG. 1.

FIG. 3 is an assembled, isometric view of FIG. 1.

FIG. 4 is a front plan view of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

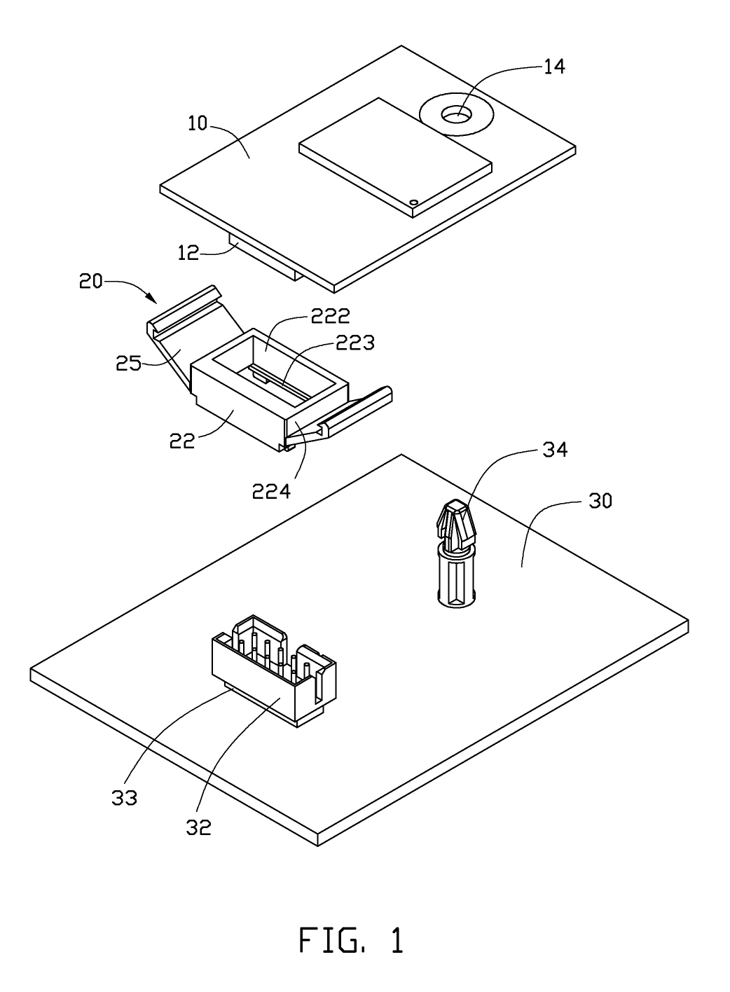

FIG. 1 shows an exemplary embodiment of an attachment mechanism for fastening an electronic component 10. The attachment mechanism includes a circuit board 30 and a fastener 20. The electronic component 10 includes a first connector 12 mounted to a first end of a side surface of the electronic component 10, and defines a through hole 14 in a second end of the electronic component 10 opposite to the first end.

A second connector 32 is fastened to the circuit board 30. Two hooking slots 33 are defined between opposite sides of a bottom of the second connector 32 and the circuit board 30. A hook 34 extends up from the circuit board 30.

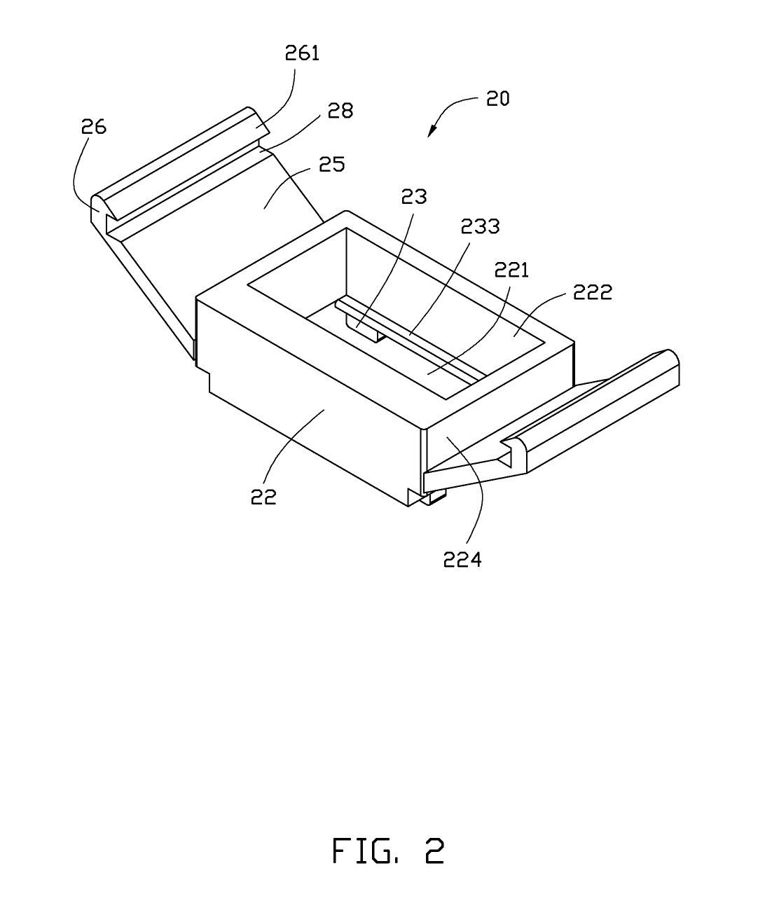

FIG. 2 shows the fastener 20 including a rectangular main body 22 and two rectangular cantilevers 25. The main body 22 includes two opposite sidewalls 222 and two end walls 224 connected between corresponding ends of the sidewalls 222. The cantilevers 25 slantingly extend up from the corresponding end walls 224. The sidewalls 222 and the end walls 224 together bound a receiving space 221. A resilient bar 223 extends from a lower portion of each sidewall 222 toward the other sidewall 222. Two supporting feet 23 extend down from a bottom surface of each sidewall 222, adjacent to the corresponding end walls 224. Two long L-shaped holding portions 26 extend from distal ends of the corresponding cantilevers 25. Each holding portion 26 extends up from the corresponding cantilever 25 and then extends toward the other holding portion 26. A guiding surface 261 is formed on a distal side of each holding portion 26, slantingly extending down. Each holding portion 26 and the corresponding cantilever 25 bound a slot 28.

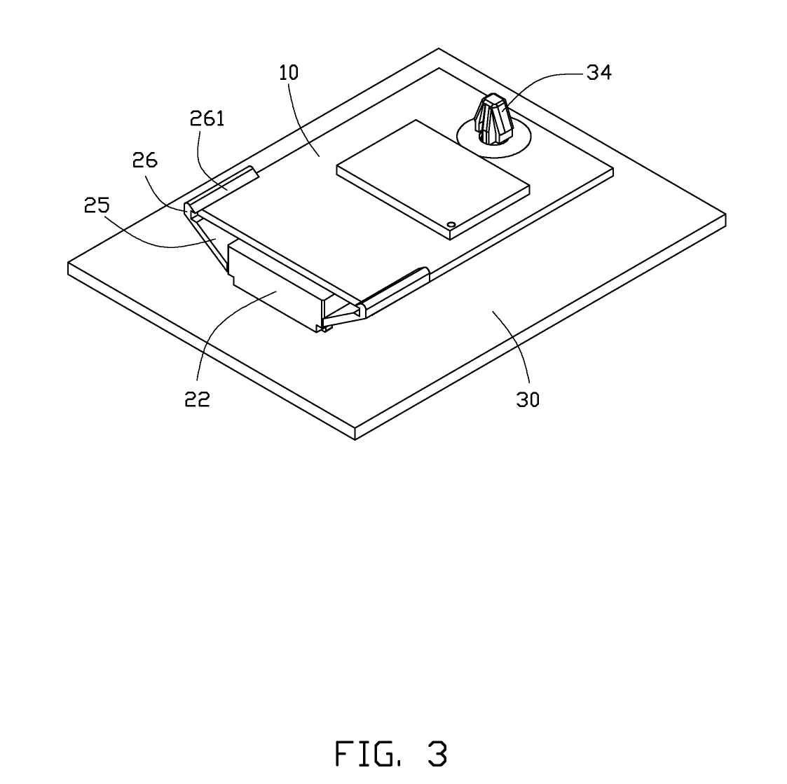

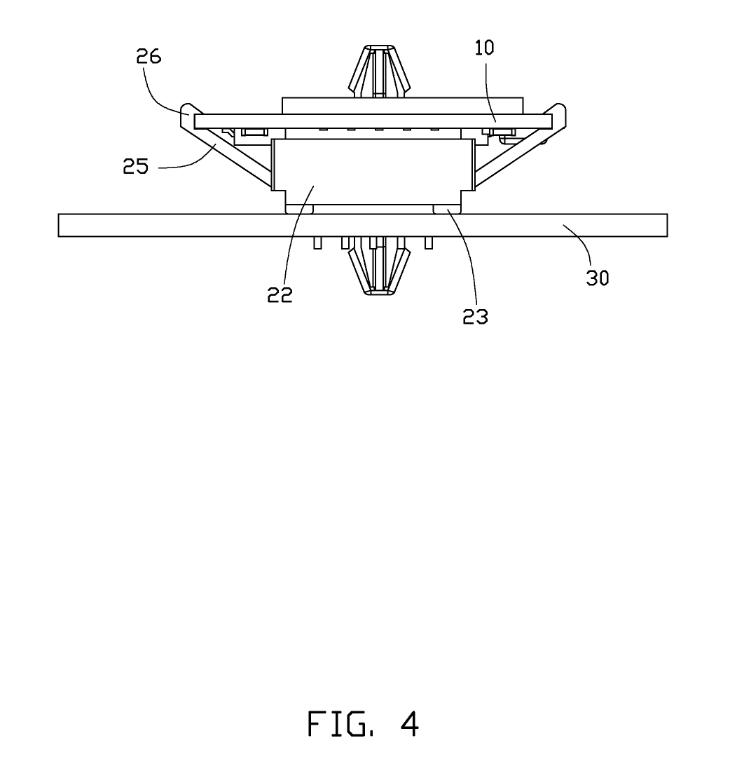

FIGS. 3 and 4 show in assembly, the fastener 20 is placed above the second connector 32, with the receiving slot 221 aligning with the second connector 32. The fastener 20 is manipulated down, the second connector 32 deforms the resilient bars 223 away from each other. When the supporting feet 23 abut against the circuit board 30, the resilient bars 223 are restored to engage in the corresponding hooking slots 33, and abut against the bottom of the second connector 32. Therefore, the attachment mechanism is assembled. The second connector 32 is received in the receiving space 221.

To fasten the electronic component 10, the first connector 12 is aligned above the second connector 32. The electronic component 10 is manipulated down. The hook 34 extends through the through hole 14, to fasten the second end of the electronic component 10. When opposite sides of the first end of the electronic component 10 abut against the guiding surfaces 261, the holding portions 26 together with the cantilevers 25 are deformed away from the electronic component 10. After the first connector 12 is connected to the second connector 32, the holding portions 26 are restored to allow opposite sides of the first end of the electronic component 10 to engage in the corresponding slots 28. Therefore, the electronic component 10 is fastened to the circuit board 30.

It is believed that the present embodiments and their advantages will be understood from the foregoing description, and various changes may be made thereto without departing from the spirit and scope of the description or sacrificing all of their materials advantages, the examples hereinbefore described merely being exemplary embodiments.

What is claimed is:

1. An attachment mechanism for fastening an electronic component, comprising:
a circuit board comprising a first connector to be connected to a second connector at a first end of the electronic component; and
a fastener comprising a main body mounted on the first connector and two cantilevers extending from opposite ends of the main body, two holding portions extending from distal ends of the corresponding cantilevers to engage with opposite sides of the electronic component.

2. The attachment mechanism of claim 1, wherein the main body defines a receiving slot for receiving the first connector, a hooking slot is defined in a side of the first connector, a resilient bar protrudes from an inner surface of a sidewall bounding the receiving slot to engage in the hooking slot.

3. The attachment mechanism of claim 1, wherein a plurality of supporting feet protrudes down from the main body to abut against the circuit board.

4. The attachment mechanism of claim 1, wherein the cantilevers slantingly extend up from the opposite ends of the main body.

5. The attachment mechanism of claim 1, wherein a guiding surface is formed on a distal side of each holding portion facing the main body.

6. The attachment mechanism of claim 1, wherein a hook extends up from the circuit board, to fasten a second end of the electronic component opposite to the first end.

7. The attachment mechanism of claim 1, wherein each holding portion and the corresponding cantilever bound a slot to receive the corresponding side of the electronic component.

8. A circuit board assembly, comprising:
a circuit board comprising a first connector;
an electronic component comprising a second connector at a first end of the electronic component to connect to the first connector; and
a fastener comprising a main body mounted on the first connector, and two cantilevers extending from opposite ends of the main body, two holding portions extending from distal ends of the cantilevers to hold opposite sides of the electronic component.

9. The circuit board assembly of claim 8, wherein the main body defines a receiving slot for receiving the first connector, a hooking slot is defined in a side of the first connector, a resilient bar protrudes from an inner surface of a sidewall bounding the receiving slot to engage in the hooking slot.

10. The circuit board assembly of claim 8, wherein a plurality of supporting feet protrudes down from the main body to abut against the circuit board.

11. The circuit board assembly of claim 8, wherein the cantilevers slantingly extend up from the main body toward the electronic component.

12. The circuit board assembly of claim 8, wherein a guiding surface is formed on a distal side of each holding portion facing the main body.

13. The circuit board assembly of claim 8, wherein a hook extends up from the circuit board, to fasten a second end of the electronic component opposite to the first end.

14. The circuit board assembly of claim 8, wherein each holding portion and the corresponding cantilever bound a slot to receive the corresponding side of the electronic component.
